(19) United States
(12) Patent Application Publication
(10) Pub. No.: US 2026/0075984 A1
(43) Pub. Date: Mar. 12, 2026

(54) SEMICONDUCTOR PACKAGE AND MANUFACTURING METHOD OF SEMICONDUCTOR PACKAGE

(71) Applicant: Taiwan Semiconductor Manufacturing Company, Ltd., Hsinchu (TW)

(72) Inventors: Ming-Fa Chen, Taichung City (TW); Chih-Tsung Tsai, Tainan City (TW)

(73) Assignee: Taiwan Semiconductor Manufacturing Company, Ltd., Hsinchu (TW)

(21) Appl. No.: 18/826,184

(22) Filed: Sep. 6, 2024

(51) Int. Cl. H01L 31/0232; G02B 6/12; G02B 6/122; H01L 23/00; H01L 23/31; H01L 25/16

(52) U.S. Cl. CPC H10F 77/407; G02B 6/122; H10W 90/00; G02B 2006/12102; G02B 2006/12104; H10W 72/07331; H10W 74/111; H10W 80/312; H10W 80/327; H10W 90/734; H10W 90/792

(57) ABSTRACT

A semiconductor package includes a photonic die including an optical coupler, an electronic die bonded over the photonic die, and a optical support bonded over the electronic die and includes a plurality of lens structures, wherein light from an external optical signal source is coupled to the optical coupler sequentially through the plurality of lens structures.

### BACKGROUND

As data networks scale to meet ever-increasing bandwidth requirements, the shortcomings of copper data channels are becoming apparent. Signal attenuation and crosstalk due to radiated electromagnetic energy are the main impediments encountered by designers of such systems. They can be mitigated to some extent with equalization, coding, and shielding, but these techniques require considerable power, complexity, and cable bulk penalties while offering only modest improvements in reach and very limited scalability. Free of such channel limitations, optical communication has been recognized as the successor to copper links. However, contemporary optical communication systems are expensive and complicated in manufacturing process.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 8 illustrate cross sectional views of intermediate stages in the manufacturing of a semiconductor package according to some exemplary embodiments of the present disclosure.

FIG. 9 and FIG. 10 illustrate cross sectional views of semiconductor packages according to different exemplary embodiments of the present disclosure.

FIG. 11 to FIG. 16 illustrate partial cross sectional views of intermediate stages in the manufacturing of a lens structure on a semiconductor package according to some exemplary embodiments of the present disclosure.

FIG. 17 to FIG. 21 illustrate partial cross sectional views of intermediate stages in the manufacturing of a lens structure on a semiconductor package according to other exemplary embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

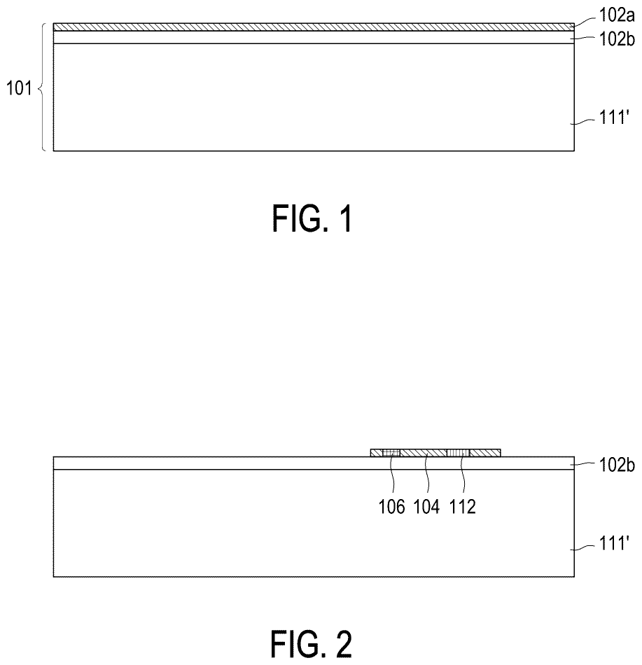

FIG. 1 to FIG. 8 illustrate cross sectional views of intermediate stages in the manufacturing of a semiconductor package according to some exemplary embodiments of the present disclosure. Referring to FIG. 1, a substrate 101 is provided, in accordance with some embodiments. In some embodiment, the substrate 101 may be a dielectric substrate formed of, for example, silicon oxide. In the present embodiment, the substrate 101 may be a silicon on insulator (SOI) substrate. For example, the substrate 101 may include an oxide layer 102b formed over a carrier substrate 111′, and a silicon layer 102a formed over the oxide layer 102b. The carrier substrate 111′ may be, for example, a material such as a glass, ceramic, dielectric, a semiconductor, the like, or a combination thereof. In some embodiments, the carrier substrate 111′ may be a semiconductor substrate, such as a bulk semiconductor or the like, which may be doped (e.g., with a p-type or an n-type dopant) or undoped. Integrated circuit devices may be formed on and/or in the carrier substrate 111′. In accordance with some embodiments of the present disclosure, the integrated circuit devices may include active devices such as transistors and/or diodes (which may include photo diodes). The integrated circuit devices may also include passive devices such as capacitors, resistors, or the like. In accordance with alternative embodiments of the present disclosure, no active devices are formed, while passive devices may be formed on/in the carrier substrate 111′. The carrier substrate 111′ may be a wafer, such as a silicon wafer (e.g., a 12-inch silicon wafer). Other substrates, such as a multi-layered or gradient substrate may also be used. In some embodiments, the semiconductor material of the substrate 102C may include silicon; germanium; a compound semiconductor including silicon carbide, gallium arsenic, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; or combinations thereof. The carrier substrate 111′ may have a thickness in the range of about 300 μm to about 2000 μm, in some embodiments. The oxide layer 102b may be, for example, a silicon oxide or the like. In some embodiments, the oxide layer 102b may have a thickness in the range of about 0.5 μm to about 4 μm, in some embodiments. The silicon layer 102a may have a thickness in the range of about 0.1 μm to about 1.5 μm, in some embodiments. Other thicknesses are possible. The substrate 101 may be referred to as having a front side or front surface (e.g., the side facing upwards in FIG. 1), and a back-side or back surface (e.g., the side facing downwards in FIG. 1). The term “about” can be used to include any numerical value that can vary without changing the basic function of that value. When used with a range, “about” also discloses the range defined by the absolute values of the two endpoints, e.g., “about 2 to about 4” also discloses the range “from 2 to 4.” The term “about” may refer to plus or minus 10% of the indicated number.

Referring to FIG. 2, the silicon layer 102a is patterned to form silicon regions for waveguides 104, photonic components 106, and optical couplers 112, in accordance with some embodiments. In this manner, the silicon layer 102a may be considered an “optical layer” in some cases. The silicon layer 102a may be patterned using suitable photo-lithography and etching techniques. For example, a hardmask layer (e.g., a nitride layer or other dielectric material, not shown in FIG. 2) may be formed over the silicon layer 102a and patterned, in some embodiments. The pattern of the hardmask layer may then be transferred to the silicon layer 102a using an etching process. The etching process may include, for example, a dry etching process and/or a wet etching process. The etching process may be anisotropic. For example, the silicon layer 102a may be etched to form recesses defining the waveguides 104 (also referred to as silicon waveguides 104), with sidewalls of the remaining unrecessed portions defining sidewalls of the waveguides 104. In some embodiments, more than one photolithography and etching sequence may be used in order to pattern the silicon layer 102a.

One waveguide 104 or multiple waveguides 104 may be patterned from the silicon layer 102a. If multiple waveguides 104 are formed, the multiple waveguides 104 may be individual separate waveguides 104 or connected as a single continuous structure. In some embodiments, one or more of the waveguides 104 form a continuous loop. Other configurations or arrangements of waveguides 104, the photonic components 106, or the optical couplers 112 are possible, and other types of photonic components 106 or photonic structures may be formed. In some cases, the waveguides 104, the photonic components 106, and the grating couplers 112 may be collectively referred to as “the photonic layer” or as a “photonic integrated circuit (PIC).”

The photonic components 106 may be integrated with the waveguides 104, and may be formed with the silicon waveguides 104. The photonic components 106 may be optically coupled to the waveguides 104 and may interact with optical signals within the waveguides 104. The photonic components 106 may include, for example, photonic devices such as photodetectors, modulators, other photonic devices, or the like. For example, a photodetector may be optically coupled to the waveguides 104 to detect optical signals within the waveguides 104 and generate electrical signals corresponding to the optical signals. As another example, a modulator may be optically coupled to the waveguides 104 to receive electrical signals and generate corresponding optical signals within the waveguides 104 by modulating optical power within the waveguides 104. In this manner, the photonic components 106 can facilitate the input/output (I/O) of optical signals to and from the waveguides 104. In other embodiments, the photonic components may include other active or passive components, such as laser diodes, optical signal splitters, phase shifters, interferometers, oscillators, or other types of photonic structures or devices.

In some embodiments, photodetectors may be formed by partially etching regions of the waveguides 104 and growing epitaxial material on the remaining silicon of the etched regions. The waveguides 104 may be etched using acceptable photolithography and etching techniques. The epitaxial material may comprise, for example, a semiconductor material such as germanium, which may be doped or undoped. In some embodiments, an implantation process may be performed to introduce dopants within the silicon of the etched regions as part of the formation of the photodetectors. The silicon of the etched regions may be doped with p-type dopants, n-type dopants, or a combination. In some embodiments, modulators may be formed by, for example, partially etching regions of the waveguides 104 and then implanting appropriate dopants within the remaining silicon of the etched regions. The waveguides 104 may be etched using acceptable photolithography and etching techniques. In some embodiments, the etched regions used for the photodetectors and the etched regions used for the modulators may be formed using one or more of the same photolithography or etching steps. The silicon of the etched regions may be doped with p-type dopants, n-type dopants, or a combination thereof. In some embodiments, the etched regions used for the photodetectors and the etched regions used for the modulators may be implanted using one or more of the same implantation steps.

In some embodiments, one or more optical coupler 112 may be formed with the waveguides 104. In one embodiment, the optical coupler 112 is, for example but not limited thereto, a grating coupler, or the like. In such embodiment, the top portions of the optical coupler 112 may have grating, so that the optical coupler 112 have the function of receiving light or transmitting light. The optical coupler 112 used for receiving light receive the light from the overlying light source or optical signal source (such as optical fiber, etc.) and transmit the light to waveguide 104. The optical coupler 112 used for transmitting light receives light from waveguide 104 and transmit light to the optical fiber or a waveguide of another photonic system.

In some embodiments, the optical coupler 112 may be formed using acceptable photolithography and etching techniques. In an embodiment, the optical coupler 112 are formed after the waveguides 104 are defined. For example, a photoresist may be formed on the waveguides 104 and patterned, with the pattern of the photoresist corresponding to the optical coupler 112. One or more etching processes may then be performed on the waveguides 104 using the patterned photoresist as an etching mask to form the optical coupler 112. The etching processes may include one or more dry etching processes and/or wet etching processes, which may include anisotropic processes. In some embodiments, other types of couplers (not individually labeled in the figures) may be formed, such as a structure that couples optical signals between the waveguides 104 and other waveguides of the semiconductor package, such as nitride waveguides. Edge couplers (not shown in the figures) may also be formed that allow optical signals and/or optical power to be transferred between the waveguide 104 and a photonic component that is horizontally mounted near a sidewall of the semiconductor package. These and other photonic structures are considered within the scope of the present disclosure.

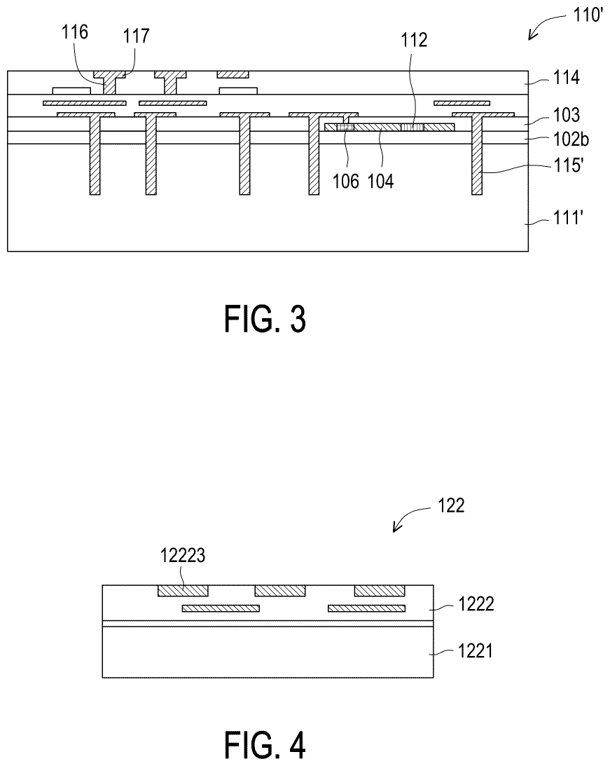

Referring to FIG. 3, a dielectric layer 103 is formed over the optical layer to form a photonic routing structure. That is, the dielectric layer 103 is formed over the waveguides 104, the photonic components 106, the optical couplers 112, and the oxide layer 102b. The dielectric layer 103 may be formed of one or more layers of silicon oxide, silicon nitride, a combination thereof, or the like, and may be formed by CVD, PVD, atomic layer deposition (ALD), a spin-on-dielectric process, the like, or a combination thereof. In some embodiments, the dielectric layer 108 may be formed by a high density plasma chemical vapor deposition (HDP-CVD), a flowable CVD (FCVD) (e.g., a CVD-based material deposition in a remote plasma system and post curing to convert it to another material, such as an oxide), the like, or a combination thereof. Other dielectric materials formed by any acceptable process may be used. In some embodiments, the dielectric layer 103 is then planarized using a planarization process such as a chemical-mechanical polish (CMP) process, a grinding process, or the like. In some cases, a thinner dielectric layer 103 may allow for more efficient optical coupling between the grating coupler 112 and a vertically-mounted photonic component, or more efficient optical coupling between the waveguides 104 and overlying waveguides, such as the nitride waveguides. In other embodiments, the planarization process may expose surfaces of the waveguides 104, the photonic components 106, and/or the grating couplers 112.

Due to the difference in refractive indices of the materials of the waveguides 104 and dielectric layer 103, the waveguides 104 have high internal reflections such that light is substantially confined within the waveguides 104, depending on the wavelength of the light and the refractive indices of the respective materials. In an embodiment, the refractive index of the material of the waveguides 104 is higher than the refractive index of the material of the dielectric layer 103. For example, the waveguides 104 may comprise silicon, and the dielectric layer 103 may comprise silicon oxide and/or silicon nitride. Accordingly, the waveguides 104 may be referred to as “silicon waveguides” herein.

Then, an interconnect structure 114 is formed over the dielectric layer 103 and the photonic layer including the optical coupler 112, in accordance with some embodiments. The interconnect structure 114 includes a plurality of dielectric layers and metal lines and vias. The dielectric layers may be formed of a light-transparent material such as silicon oxide. The dielectric layers may also be formed of silicon oxynitride, silicon nitride, or the like, or low-k dielectric materials having k values lower than about 3.0. The low-k dielectric materials may include Black Diamond (a registered trademark of Applied Materials), a carbon-containing low-k dielectric material, Hydrogen SilsesQuioxane (HSQ), MethylSilsesQuioxane (MSQ), or the like. The metal lines and vias 116 may be formed using damascene processes, and may include, for example, copper on diffusion barrier layers. The diffusion barrier layers may be formed of titanium, titanium nitride, tantalum, tantalum nitride, or the like.

In some embodiments, one or more nitride waveguides (not shown) may be formed within the interconnect structure 114. In some embodiments, nitride waveguides (also referred to as “silicon nitride waveguides”) may be optically coupled to overlying or underlying nitride waveguides. In some embodiments, one or more of the bottom-most nitride waveguides may be coupled to one or more underlying silicon waveguides 104. In this manner, the nitride waveguides may be used to transmit optical signals and/or optical power to or from other nitride waveguides and/or the silicon waveguide(s) 104.

In some cases, a waveguide formed from silicon nitride (e.g., nitride waveguides) may have advantages over a waveguide formed from silicon (e.g., waveguides 104). For example, silicon nitride has a higher dielectric constant than silicon, and thus a nitride waveguide may have a greater internal confinement of light than a silicon waveguide. This may also allow the performance or leakage of nitride waveguides to be less sensitive to process variations, less sensitive to dimensional uniformity, and less sensitive to surface roughness (e.g., edge roughness or linewidth roughness). In some cases, the reduced process sensitivity may allow nitride waveguides to be easier or less costly to process than silicon waveguides. These characteristics may allow a nitride waveguide to have a lower propagation loss than a silicon waveguide. In some cases, the propagation loss (dB/cm) of a nitride waveguide may be between about 0.1% and about 50% of a silicon waveguide. In some cases, a nitride waveguide may also be less sensitive to the temperature of the environment than a silicon waveguide. For example, a nitride waveguide may have a sensitivity to temperature that is as small as about 1% of that of a silicon waveguide.

In some embodiments, a plurality of bonding pads 117 are formed over and connected to metal lines/vias 116. At this point, a photonic die 110′ including the optical coupler 112 is substantially formed. The bonding pads 117 may be formed of aluminum copper, but the disclosure is not limited thereto. The bonding pads 117 are electrically connected to the integrated circuit devices and/or buried vias 115′ through interconnect structure 114, which the integrated circuit devices may be light to electrical conversion devices and/or electrical to light conversion devices. The light to electrical conversion devices and/or electrical to light conversion devices may be built inside the photonic die 110′ or external to and attached to the photonic die 110′. The light to electrical conversion devices may include photo diodes. The electrical to light conversion devices may include light emitting didoes, lamps, or the like.

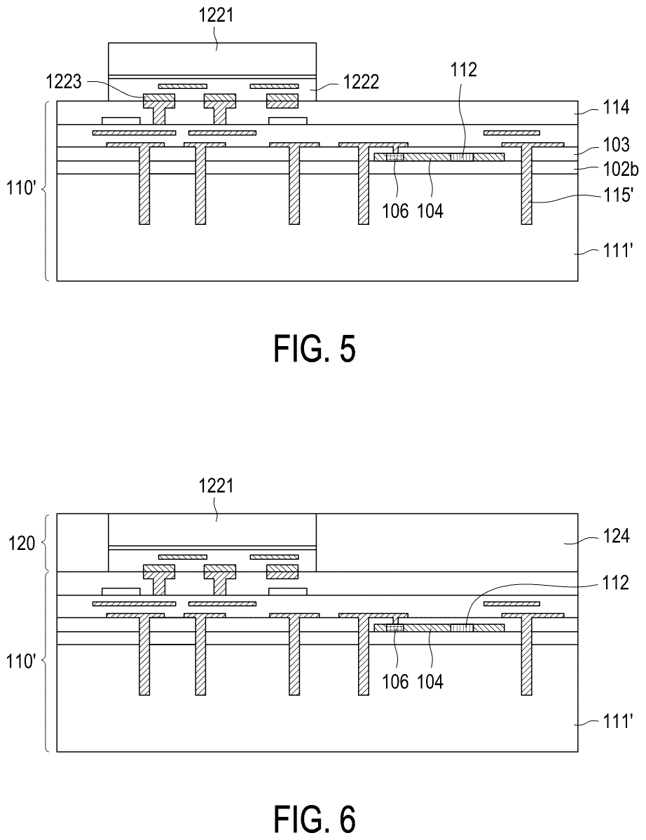

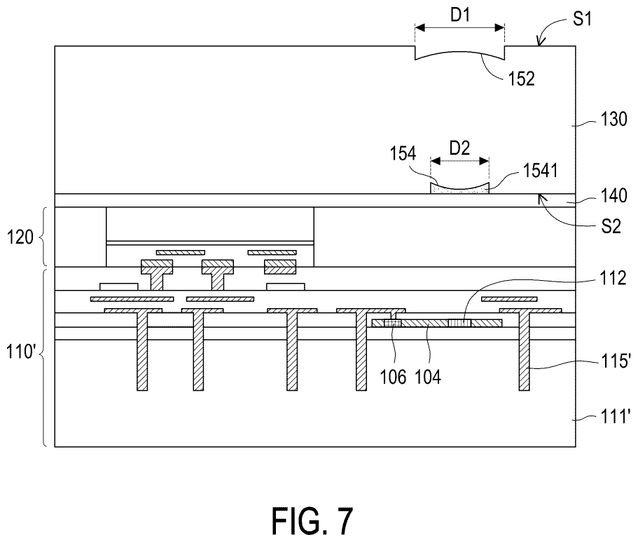

In accordance with some embodiments of the disclosure, the photonic die 110′ shown in FIG. 3 may be a part of a wafer, which includes a plurality of (identical) photonic dies 110′ arranged as an array, although one photonic die 110′ is illustrated herein. In some embodiments, the photonic die 110′ includes the optical coupler 112, which is configured to be optically coupled to an optical signal source (e.g., optical signal source 180 shown in FIG. 7), such as optical fibers, or the like. Namely, the photonic die 110′ has functions of receiving optical signals, transmitting the optical signals inside the photonic die 110′, transmitting the optical signals out of the photonic die 110′, and communicating electronically with an electronic die (e.g., the electronic die 120 shown in FIG. 5). Accordingly, the photonic die 110′ is also responsible for the input-output (IO) of the optical signals in a photonic package (also referred to as an optical engine), which may be part of a semiconductor package or other structure.

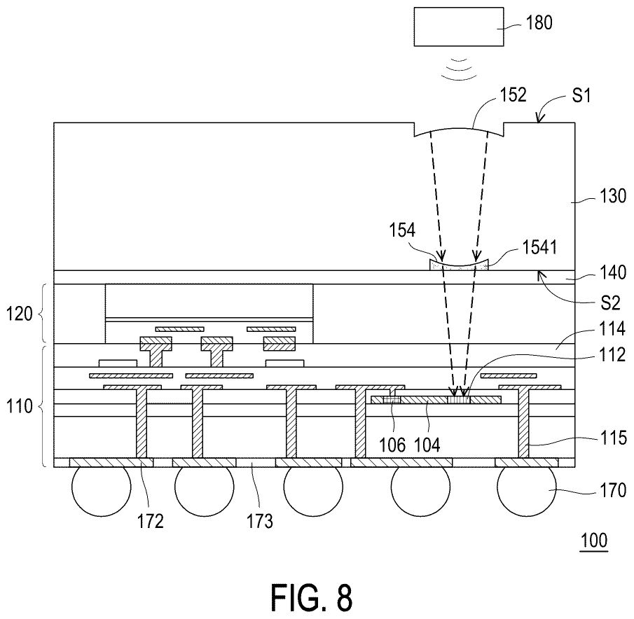

In accordance with some embodiments of the present disclosure, the photonic die 110′ may be used as an interposer, and includes through vias (also referred to as through substrate vias or through silicon vias) penetrating through the substrate. Such through vias (e.g., the through vias 115 shown in FIG. 8) are formed of a conductive material, which may also be a metallic material such as tungsten, copper, titanium, or the like. The process of forming through vias may start with a plurality of blind vias 115′ as it is shown in FIG. 3, and eventually exposed such that the metal is substantially coplanar with the back surface of the substrate as it is shown in FIG. 8.

With now reference to FIG. 4 and FIG. 5, an electronic die 122 is provided and bonded over the photonic die 110′. The electronic die 122 may be, for example, a semiconductor device, die, or chip that may communicate with the photonic components 106 using electrical signals. In some embodiments, the electronic die 122 may process electrical signals received from photonic components 106 or may generate electrical signals that photonic components 106 convert into optical signals. One electronic die 122 is shown in FIG. 5, but a semiconductor package may include two or more electronic dies 122 in other embodiments in order to reduce processing cost or increase functionality. The electronic die 122 includes connectors (e.g., bonding pads 1223), which may be, for example, conductive pads, conductive pillars, or the like. In some embodiments, the electronic die 122 may have a thickness in the range of about 10 μm to about 35 μm. Other thicknesses are possible.

The electronic die 122 may include integrated circuits for interfacing with the photonic components 106, such as circuits for controlling the operation of the photonic components 106. For example, the electronic die 122 may include controllers, drivers, transimpedance amplifiers, the like, or combinations thereof. The electronic die 122 may include a CPU or memory functionality, in some embodiments. In some embodiments, the electronic die 122 includes circuits for processing electrical signals received from photonic components 106, such as for processing electrical signals received from a photonic component 106 comprising a photodetector. The electronic die 122 may control high-frequency signaling of the photonic components 106 according to electrical signals (digital or analog) received from another device or die, in some embodiments. In some embodiments, the electronic die 122 may be an electronic integrated circuit (EIC) or the like that provides Serializer/Deserializer (SerDes) functionality. In this manner, the electronic die 122 may act as part of an I/O interface between optical signals and electrical signals within a photonic package 100. In some cases, the photonic packages 100 described herein can be considered system-on-chip (SoC) or system-on-integrated-circuit (SoIC) devices.

In some embodiments, the electronic die 122 is bonded to the interconnect structure 114 of the photonic die 110′ using dielectric-to-dielectric bonding and/or metal-to-metal bonding (e.g., direct bonding, fusion bonding, oxide-to-oxide bonding, hybrid bonding, or the like). In such embodiments, dielectric-to-dielectric bonding may occur between the top-most dielectric layer of the photonic die 110′ and a bonding layer (not individually shown) of the electronic die 122. During the bonding, metal-to-metal bonding may also occur between the bonding pads 1223 of the electronic die 122 and the top-most bonding pads 117 of the photonic die 110′.

In accordance with some embodiments of the present disclosure, the electronic die 122 is not overlapped with the optical coupler 112 from a top view, so the optical coupler 112 can be optically coupled to the optical signal source 180 (FIG. 7) without being interfered by the electronic die 122.

In some embodiments, the electronic die 122 may firstly be a part of a wafer, which includes a plurality of electronic dies 122 arranged as an array, and then be diced into a plurality of (separated) electronic dies 122. The electronic dies 122 may include a substrate 1221, an interconnect structure 1222 including a plurality of dielectric layers and metal lines and vias. The dielectric layers may also be formed of silicon oxide, silicon oxynitride, silicon nitride, or the like, or low-k dielectric materials having k values lower than about 3.0. The low-k dielectric materials may include Black Diamond (a registered trademark of Applied Materials), a carbon-containing low-k dielectric material, Hydrogen SilsesQuioxane (HSQ), MethylSilsesQuioxane (MSQ), or the like. The metal lines and vias may be formed using damascene processes, and may include, for example, copper on diffusion barrier layers. The diffusion barrier layers may be formed of titanium, titanium nitride, tantalum, tantalum nitride, or the like. The bonding pads 1223 are formed over and connected to metal lines/vias. The bonding pads 1223 may be formed of aluminum copper, but the disclosure is not limited thereto.

In the present embodiment, the photonic die 110′ is in a wafer form, and the diced electronic dies 122 may be picked and placed over the photonic die 110′. That is to say, the bonding process shown in FIG. 5, in the present embodiment, is a die to wafer process. It is noted that more or less dies may be provided on the photonic die 110′. In the present embodiment, the electronic die 122 is bonded with the photonic die 110′ by die to wafer bonding process. For example, direct metal to metal thermal compression bonding, or any type of hybrid bonding technique may be applied. After the bonding process, the bonding pads 1223 of the electronic die 122 are bonded to the bonding pads 117 of the photonic die 110′ respectively.

With now reference to FIG. 6, an encapsulating material 124 is provided over the photonic die 110′. The encapsulating material 124 at least laterally encapsulates the electronic die 122. In some embodiments, the encapsulating material 124 may be formed of a light-transparent material such as silicon oxide, or any other suitable oxide material. In some embodiments, an upper surface of the encapsulating material 124 may be firstly higher than an upper surface of the electronic die 122. Namely, the encapsulating material 124 may firstly cover the upper surface of the electronic die 122.

Then, a thinning process may be performed on the encapsulating material 124 to reveal the upper surface of the electronic die 122 for further processing. The thinning process may be, for example, a mechanical grinding or CMP process whereby chemical etchants and abrasives are utilized to react and grind away the encapsulating material 124 until the electronic die 122 has been revealed. The resulting structure is shown in FIG. 4. After the thinning process is performed, the upper surface of the electronic die 122 is substantially level with the upper surface of the encapsulating material 124. However, while the CMP process described above is presented as one illustrative embodiment, it is not intended to be limiting to the embodiments. Any other suitable removal process may alternatively be used to thin the encapsulating material 124 and the electronic die 122. For example, a series of chemical etches or any other suitable process may alternatively be utilized, and all such processes are fully intended to be included within the scope of the embodiments. In an alternative embodiment, the thinning process may be omitted, and the encapsulating material 124 may cover or reveal the upper surface of the electronic die 122. Throughout the description, the resultant structure including the electronic die 122 and the encapsulating material 124 is referred to as an encapsulated electronic device 120, which may have a wafer form in the process.

Then, referring to FIG. 7, an optical support 130 (also referred to as supporting substrate) is bonded over the encapsulated electronic die 120 through a bonding layer 140, in accordance with some embodiments. The optical support 130 is a rigid structure that is attached to the encapsulated electronic die 120 in order to provide structural or mechanical stability. The use of the optical support 130 can reduce warping or bending, which can improve the performance of the optical structures such as the waveguides 104 or photonic components 106. The optical support 130 may be attached to the encapsulated electronic die 120 (e.g., to the encapsulating material 124 and/or the electronic dies 122) using the bonding layer 140 formed over the encapsulating material 124 and the electronic dies 122, in accordance with some embodiments. The bonding layer 140 may be an adhesive layer or may be a dielectric layer used for dielectric-to-dielectric bonding of the optical support 130, for example. A dielectric bonding layer 140 may be a dielectric material suitable for bonding. In some embodiments, a planarization process is performed on the bonding layer 140. In other embodiments, a bonding layer 140 is not formed. In other embodiments, t he bonding layer 140 may be an oxide material same or similar to the encapsulating material 124, so the optical support 130 is bonded to the encapsulated electronic die 120 through oxide bonding. In some embodiments, the bonding layer 140 may be a high thermal conductive hybrid bonding layer, which may include diamond-like carbon (DLC) coating, silicon carbide coating, Cu-SiOx coating, SiON coating, or the like.

The optical support 130 may include one or more materials such as silicon (e.g., a silicon wafer, bulk silicon, or the like), a silicon oxide, a metal, an organic core material, the like, or another type of material. In some embodiments, the optical support 130 may include a semiconductor element, such as germanium (Ge), or a compound semiconductor, such as silicon carbide (SiC), gallium arsenide (GaAs), indium arsenide (InAs), or indium phosphide (InP). The optical support 130 may have a thickness in the range of about 500 μm to about 700 μm, in some embodiments. The optical support 130 may also have lateral dimensions (e.g., length, width, and/or area) that are greater than, about the same as, or smaller than those of the structure. In some embodiments, the optical support 130 includes a bonding layer (not separately illustrated), which may be an adhesive layer or a layer suitable for bonding to the bonding layer 140.

In some embodiments, the optical support 130 is formed of materials transparent to relevant wavelengths of light such that optical signals may be transmitted through the optical support 130. In the example of FIG. 7, a plurality of lens structures (e.g., the first lens structure 152 and the second lens structure 154) is formed over the optical support 130. The lens structures 152, 154 may facilitate improved optical coupling between the optical coupler 112 and an external optical signal source (e.g., optical fiber 180 in FIG. 8). Referring to FIG. 7 and FIG. 8, light from the external optical signal source is coupled to the optical coupler 112 of the photonic die 110′ sequentially through the first lens structure 152 and the second lens structure 154. That is, light from the optical signal source firstly passes through the first lens structures 152 and then passes through the second lens structures 154 to further focus (e.g., modify/reduce) the beam size of the light that is projected on the optical coupler 112. In such embodiments, a size (e.g., diameter D1) of the first lens structure 152 is substantially greater than a size (e.g., diameter D2) of the second lens structure 154 for further focusing the light that is coupled to the optical coupler 112. In some embodiments, the lens structures 152, 154 are pre-formed on the optical support 130 and the optical support 130 is then bonded to the encapsulated electronic die 120.

With the configuration of the optical support 130 for providing mechanical strength to the semiconductor package, the distance between the optical signal source 180 to the optical coupler 112 is increased, which may result in decadence and/or divergence of light beams from the optical signal source. Accordingly, multiple lens structure 152, 154 are configured to focus light beams from the optical signal source, so the optical coupler 112 can be optically coupled to the optical signal source through the lens structures 152, 154. In addition, one of the lens structures (e.g., the first lens structure 152) can be used for collimating light from/to the optical signal source 180, another one of the lens structures (e.g., the second lens structure 154) is for modifying (e.g., reducing) the beam size of the light projected on the optical coupler 112. Accordingly, the beam size of the light projected on the optical coupler 112, such as grating coupler (GC) and/or edge coupler (EC), is tunable, and can be tuned to match different optical coupler (e.g., grating couplers and/or edge couplers) designs to optimize the coupling efficiency.

Referring to FIG. 7 and FIG. 8, in the present embodiment, the first lens structure 152 and the second lens structure 154 are disposed on two opposite surfaces of the optical support 130 respectively. For example, the second lens structure 154 is disposed on a lower surface S2 of the optical support 130 that is bonded to the encapsulated electronic die 120, and the first lens structure 152 is disposed on an upper surface S1 of the optical support 130 that is opposite to the lower surface S2. In the embodiment, the second lens structure 154, that is formed on the lower surface S2 to be bonded to the encapsulated electronic die 120, is filled with a filling material 1541, so that a top surface of the filling material 1541 is substantially coplanar with the surface S2 of the optical support 130. The filling material 1541 may include inorganic material such as, but not limited to, aluminum oxide (Al₂O₃), silicon dioxide (SiO₂), silicon nitride (SiNx), or the like. In some embodiments, the material of the filling material 1541 may be the same or similar to that of the encapsulating material 124, which is light-transparent oxide material.

The optical signal source 180 is disposed over substrate and is optically coupled to the first lens structure 152 on the upper surface S1. In some embodiments, the second lens structure 154 overlaps with the optical coupler 112 from a top view, and the first lens structure 152 overlaps with the second lens structure 154 from a top view. As such, light from the optical signal source 180 firstly passes through the first lens structures 152 and the light sequentially passes through the second lens structures 154 to be further focused and coupled to the optical coupler 112. The beam size of the light projected on the optical coupler 112 can be precisely tuned to match different optical coupler designs by adjusting the sizes and positions of the first lens structure 152 and the second lens structure 154. It is noted that two lens structures are illustrated in the embodiments, however, the disclosure is not limited thereto. More lens structures may be formed on the optical support 130 to meet different optical requirements of the semiconductor packages.

With now reference to FIG. 7 and FIG. 8, after the optical support 130 is bonded to the encapsulated electronic die 120, the resultant structure shown in FIG. 7 is then flipped over and attached to a carrier (not shown), in accordance with some embodiments. The carrier may be, for example, a wafer (e.g., a silicon wafer), a panel, a glass substrate, a ceramic substrate, or the like. The structure may be attached to the carrier using, for example, an adhesive or a release layer (not shown). The back side of the carrier substrate 111′ is then thinned till ends of the blind via 115′ is exposed, so as to form the through (substrate) vias 115 as shown in FIG. 8. The carrier substrate 111 may be thinned by a CMP process, a mechanical grinding, an etching process, the like, or a combination thereof.

Then, a plurality of conductive pads 172 are formed over the through vias 115 and the carrier substrate 111, in accordance with some embodiments. The conductive pads 172 may be conductive pads or conductive pillars that are electrically connected to the interconnect structure 114. The conductive pads 172 may be formed from a conductive material such as copper, another metal or metal alloy, the like, or combinations thereof. The material of the conductive pads 172 may be formed by a suitable process, such as plating. For example, in some embodiments, the conductive pads 172 are metal pillars (such as copper pillars) formed by a sputtering, printing, electro plating, electroless plating, CVD, or the like. The metal pillars may be solder free and have substantially vertical sidewalls. In some embodiments, a metal cap layer (not shown) is formed on the top of the conductive pads 172. The metal cap layer may include nickel, tin, tin-lead, gold, silver, palladium, indium, nickel-palladium-gold, nickel-gold, the like, or a combination thereof and may be formed by a plating process. In some embodiments, underbump metallizations (UBMs, not shown) may be formed over the conductive pads 172. In some embodiments, a passivation layer 173 such as a silicon oxide or silicon nitride may be formed over the carrier substrate 111 to surround or partially cover the conductive pads 172.

Then, a plurality of conductive connectors 170 may be formed on the conductive pads 172 to form a semiconductor package 100, in accordance with some embodiments. The conductive connectors 170 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 170 may include a conductive material such as solder, copper, aluminum, gold, nickel, silver, palladium, tin, the like, or a combination thereof. In some embodiments, the conductive connectors 170 are formed by initially forming a layer of solder through such commonly used methods such as evaporation, electroplating, printing, solder transfer, ball placement, or the like. Once a layer of solder has been formed on the structure, a reflow may be performed in order to shape the material into the desired bump shapes. In another embodiment, the conductive connectors 170 are metal pillars (such as a copper pillar) formed by a sputtering, printing, electro plating, electroless plating, CVD, or the like. The metal pillars may be solder free and have substantially vertical sidewalls. In some embodiments, a metal cap layer (not shown) is formed on the top of the conductive connectors 170. The metal cap layer may include nickel, tin, tin-lead, gold, silver, palladium, indium, nickel-palladium-gold, nickel-gold, the like, or a combination thereof and may be formed by a plating process. In some embodiments, the conductive connectors 170 are electrically connected to the through vias 115 and may serve as electrical terminals of the semiconductor package 100.

Then, upon completion of the process described above, the resultant structure is in a wafer form, and is ready to be divided into individual semiconductor packages 100 by dicing through a plurality of scribing (dicing) lines to provide separation into individual semiconductor packages 100 shown in FIG. 8.

With such process and configuration, the electronic die 120 is directly bonded to the photonic die 110 by, for example, hybrid bonding technique to improve electrical performance of the semiconductor package 100. The optical support 130 is configured to provide mechanical strength, and the lens structure 172, 174 are configured to collimate and further focus light beams from the optical signal source. Thereby, the optical coupler 112 can be optically coupled to the optical signal source through the lens structures 172, 174, so as to avoid or at least reduce decadence and/or divergence of light beams from the optical signal source due to increase of distance between the optical signal source 180 to the optical coupler 112.

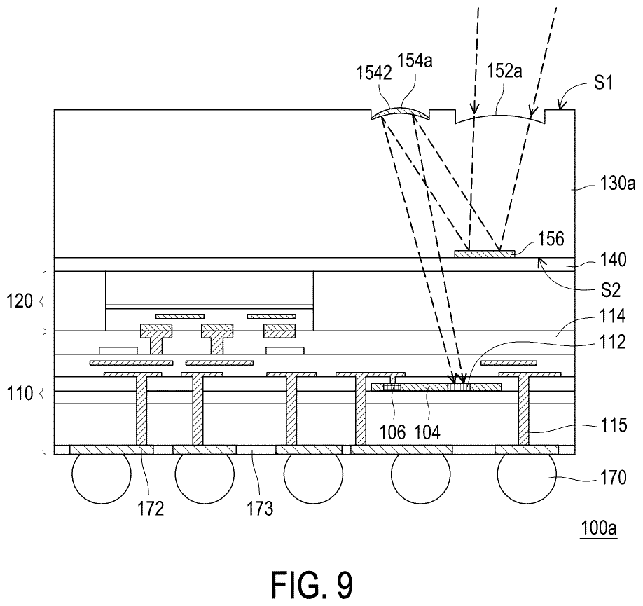

FIG. 9 illustrates a cross sectional view of a semiconductor package according to some exemplary embodiments of the present disclosure. It is noted that the semiconductor package 100a shown in FIG. 9 contains many features same as or similar to the semiconductor package disclosed in the previous embodiments. For purpose of clarity and simplicity, detail description of same or similar features may be omitted, and the same or similar reference numbers denote the same or like components.

Referring to FIG. 9, in the present embodiment, the first lens structure 152 and the second lens structure 154 are disposed on the upper surface S1 of the optical support 130 away from the encapsulated electronic die 120. In such embodiment, the semiconductor package 100a may further include a reflector 156, which is disposed on the lower surface S2 of the optical support 130 that is bonded to the encapsulated electronic die 120. In addition, one of the first lens structure 152 and the second lens structure 154 is coated with a reflective layer 1542. In the present embodiment, the reflective layer 1542 is coated on an outer surface of the second lens structure 154. Accordingly, the light from the external optical signal source (e.g., the optical fiber 180 shown in FIG. 8) passes through the first lens structures 152 and sequentially reflected by the reflector 156 and the reflective layer 1542 on the second lens structures 154, so as to be coupled to the optical coupler 112. In such embodiments, a size (e.g., diameter) of the first lens structure 152, where the light firstly passes, is substantially greater than a size (e.g., diameter) of the second lens structure 154, where the light subsequently hits, such that the second lens structure 154 with smaller dimensions can further focus the light that is coupled to the optical coupler 112.

In the embodiment, the reflector 156 may be formed underneath the first lens structure 152 to reflect light passing through the first lens structure 152 toward the second lens structure 154. In this manner, the first lens structure 152 and the second lens structure 154 can be disposed on the same surface (e.g., the upper surface S1) and can be formed simultaneously, before or after the optical support 130 is bonded to the encapsulated electronic die 120. The reflector 156 and the reflective layer 1542 may be formed by depositing reflective material, in accordance with some embodiments. The reflective material may comprise metal materials or dielectric materials that are reflective to the relevant wavelengths of light. For example, in some embodiments, the reflective material may comprise a metal such as copper, silver, gold, tungsten, cobalt, aluminum, alloys thereof, a combination thereof, or the like. The metal may be deposited using a suitable process, such as sputtering, a plating process, CVD, or the like. In some embodiments, the metal may be deposited by first depositing a seed layer and then depositing the metal on the seed layer. In other embodiments, the reflective material may comprise a dielectric material such as silicon, silicon oxide, silicon nitride, titanium oxide, tantalum oxide, titanium nitride, tantalum nitride, a combination thereof, or the like. The dielectric material may be deposited using a suitable process, such as PVD, CVD, ALD, or the like. In some embodiments, the reflective material has a thickness in the range of about 10 nm to about 1000 nm, though other thicknesses are possible. In some embodiments, the reflective material has a reflectivity greater than about 90% for appropriate wavelengths of light, though other values are possible.

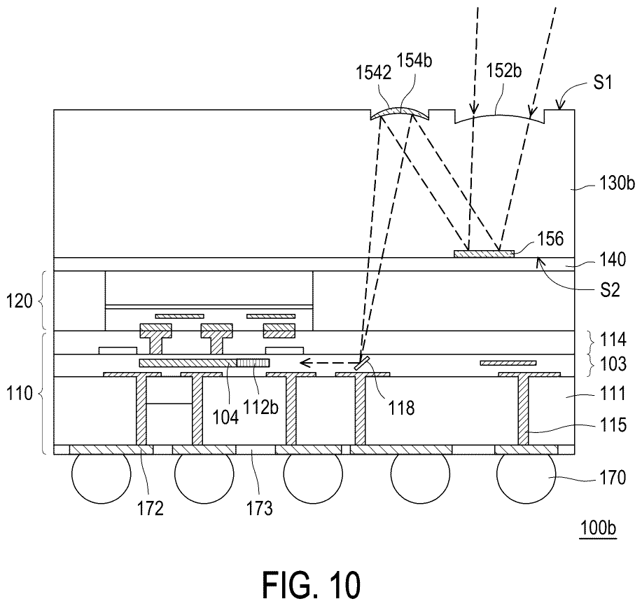

FIG. 10 illustrates a cross sectional view of a semiconductor package according to some exemplary embodiments of the present disclosure. It is noted that the semiconductor package 100b shown in FIG. 10 contains many features same as or similar to the semiconductor package disclosed in the previous embodiments. For purpose of clarity and simplicity, detail description of same or similar features may be omitted, and the same or similar reference numbers denote the same or like components.

Referring to FIG. 10, in the present embodiment, the optical coupler 112b is an edge coupler, which allow optical signals and/or optical power to be transferred to/from the waveguide 104 horizontally mounted near a sidewall of the photonic package 100. As such, the first lens structure 152 and the second lens structure 154 are disposed on the upper surface S1 of the optical support 130 away from the encapsulated electronic die 120 while the reflector 156 is disposed on the lower surface S2 of the optical support 130, and the second lens structure 154 is coated with the reflective layer 1542. In addition, the semiconductor package 100b further includes another reflector 118 disposed in the photonic die 110. In some embodiments, the reflector 118 may be formed in the dielectric layer 103 that covers the waveguide 104 and the edge coupler 112. The reflector 118 is configured in a manner that the light reflected by the reflective layer 1542 on the second lens structure 154 hits the reflector 118 and is reflected back as a horizontal light beam toward the edge coupler 112b. Accordingly, the light from the external optical signal source (e.g., the optical fiber 180 shown in FIG. 8) firstly passes through the first lens structure 152, and then sequentially reflected by the reflector 156, the reflective layer 1542 on the second lens structure 154, and the reflector 118, so as to be horizontally coupled to the edge coupler 112b. In such embodiments, a size (e.g., diameter) of the first lens structure 152, where the light firstly passes, is substantially greater than a size (e.g., diameter) of the second lens structure 154, where the light subsequently hits, such that the second lens structure 154 with smaller dimensions can further focus the light that is coupled to the edge coupler 112b.

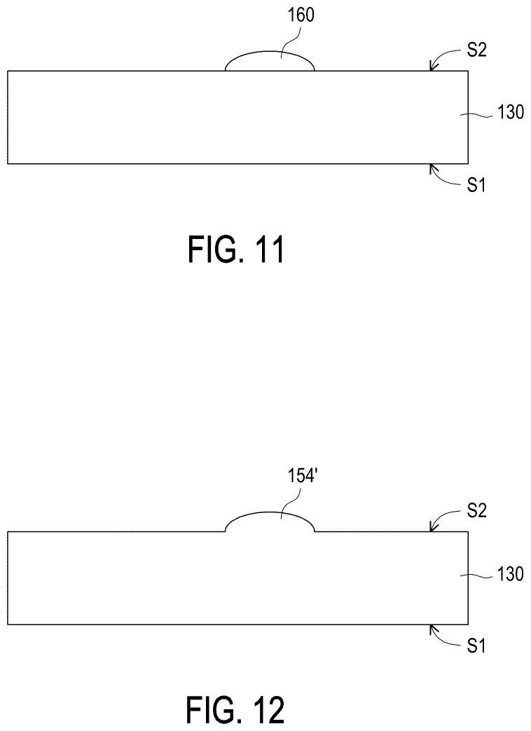

FIG. 11 to FIG. 16 illustrate partial cross sectional views of intermediate stages in the manufacturing of a lens structure on a semiconductor package according to some exemplary embodiments of the present disclosure. There are multiple methods that are suitable for forming the optical support 130 shown in FIG. 8 with the first lens structure 152 and the second lens structure 154 on two opposite surfaces of the optical support 130. FIG. 11 to FIG. 16 merely show one of the possible methods for illustrating purpose, and the disclosure is not limited thereto.

Referring to FIG. 8 and FIG. 11, in the present embodiments, a lens structure (i.e. the second lens structure 154 is firstly formed on a surface (i.e., the lower surface S2 to be bonded to the encapsulated electronic die 120) of the optical support 130. The method of forming the lens structure 154 includes the following steps. First, a patterned polymer layer 160 is formed on the surface S2 of the optical support 130. A polymer layer may be initially deposited on the optical support 130, and then be patterned using a typical photolithography process to form the patterned polymer layer 160. The patterned polymer layer 160 is a cylindrical pattern of the polymer material that covers a region where the lens structure 154 is to be formed. The patterned polymer layer 160 may be used as an etch protection layer in the etching step of the optical support 130 performed later on. In this sense, at least the surface portion of the optical support 130 may be formed of a material having an etching selectivity with the patterned polymer layer 160. For example, the patterned polymer layer 160 may be made of polyimide (PI), polyethylene (PE), polypropylene (PP), polystyrene (PS), polyvinyl alcohol (ply alcohol); PVA), polytetrafluoroethylene (PTFE), poly (methyl methacrylate) (PMMA), polyvinyl chloride (PVC), polystyrene terephthalate ( poly (ethylene terephthalate; PET), polyester, phenol resin, urea resin, urethane resin, polyurethane and the like. The patterned polymer layer 160 may be formed to an appropriate thickness, for example, 1 μm or less in consideration of the burden of patterning. The patterned polymer layer 160 may be formed using a suitable coating method or a printing method such as a spin coating method, a doctor blade coating method, an electrospray method, or the like. Then, a reflow process is performed over the patterned polymer layer 160 to form a polymer lens structure 160, which has a surface that is curved by the surface tension of the polymer is formed as it is shown in FIG. 11.

Then, referring to FIG. 12, an etching process is performed over the surface S2 of the optical support 130 with the polymer lens structure 160 disposed thereon, so as to transfer the curvy profile of the polymer lens structure 160 onto the surface S2 of the optical support 130 and form the lens structure 154′. The lens structure 154′ protruding from the surface S2 of the optical support 130 may also be used as a lens for collimating and/or focusing the light beams. However, in the present embodiment, a top surface of the lens structure 154 shown in FIG. 8 is substantially equal to or lower than the surface S2 of the optical support 130. As such, another etching process is adopted.

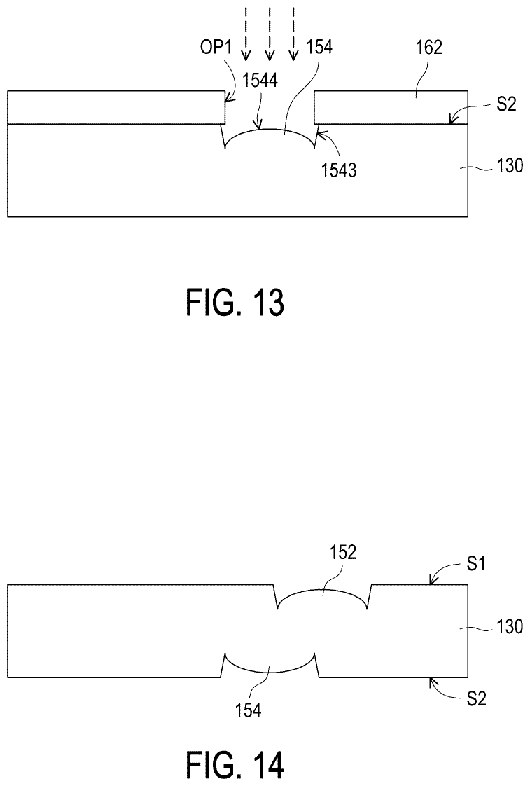

Referring to FIG. 13, a patterned mask layer 162 is provided over the surface S2 of the optical support 130 and the patterned mask layer 162 includes an opening OP1 exposing the lens structure 154′ shown in FIG. 12. Then, another etching process is performed to form the lens structure 154 shown in FIG. 13. The etching processes may include one or more dry etching processes and/or wet etching processes. In the embodiment, the etching process includes dry etching process, which involves selective material removal by means of ion-assisted processes such as ion beam etching (IBE), reactive ion etching (RIE), and inductively coupled plasma (ICP) etching, or the like, but the disclosure is not limited thereto. Accordingly, the resulting lens structure 154 includes a recess dented from an outer surface (e.g., the surface S2) of the optical support 130, and the recess includes a non-vertical sidewall 1543 and a convex bottom surface 1544, which has a rounded or spherical shape. Then, the patterned mask layer 162 is removed.

Referring to FIG. 14, the resulting structure shown in FIG. 13 is then flipped over and the first lens structure 152 is formed on the upper surface S1 of the optical support 130 by similar process illustrated in FIG. 11 to FIG. 13 on the upper surface S1 of the optical support 130.

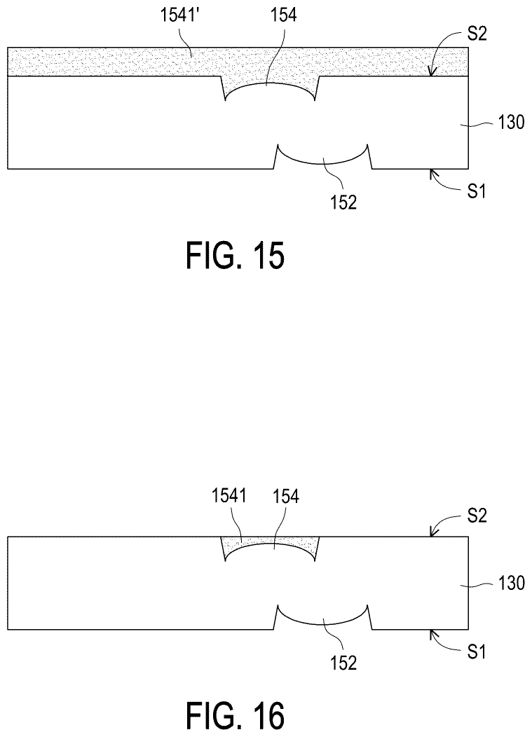

Then, referring to FIG. 15 and FIG. 16, a filling material 1541 is provided for filling the recess of the second lens structure 154. The filling material 1541 may be dispensed onto the surface S2 of the optical support 130 to form a filling material layer 1541′. The filling material layer 1541′ may be dispensed in a liquid form that has a high viscosity. After the dispensing, the filling material layer 1541′ may be cured to a solid form. Then, referring to FIG. 16, a planarization process may be performed over the filling material layer 1541′ to removed the excess filling material till the surface S2 of the optical support 130 is exposed. The planarization process may include CMP process, etching process, or the like. Accordingly, the filling material 1541 fills the recess of the second lens structure 154 and a top surface of the filling material 1541 is substantially coplanar with the surface S2 of the optical support 130. The filling material 1541 may include inorganic material such as, but not limited to, aluminum oxide (Al₂O₃), silicon dioxide (SiO₂), silicon nitride (SiNx), or the like. In some embodiments, the material of the filling material 1541 may be the same or similar to that of the encapsulating material 124, which is light-transparent oxide material.

After the filling material 1541 is filled in the recess of the second lens structure 154, the lower surface S2 of the optical support 130 with the second lens structure 174 filled with the filling material 1541 is then bonded to the encapsulated electronic die 120 as it is shown in FIG. 8. It is noted that, in other embodiment, the filling material 1541 may be provided right after the second lens structure 174 is formed, and then the optical support 130 is flipped to form the first lens structure 172 on the upper surface S1. The disclosure does not limit the process order disclosed herein.

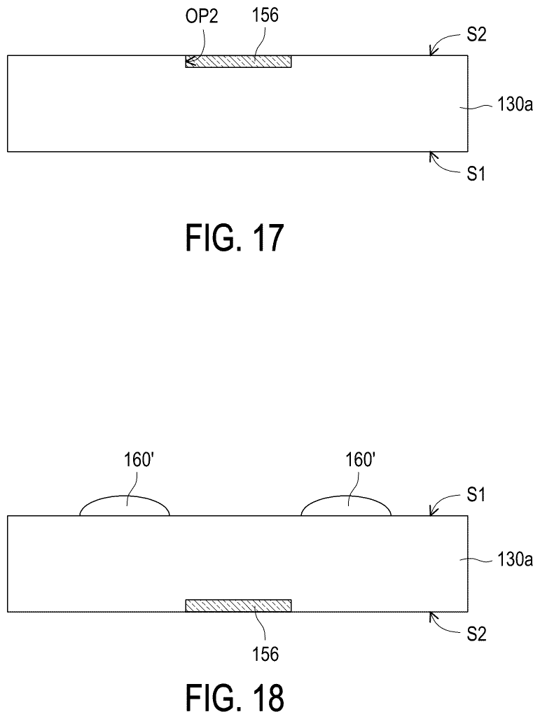

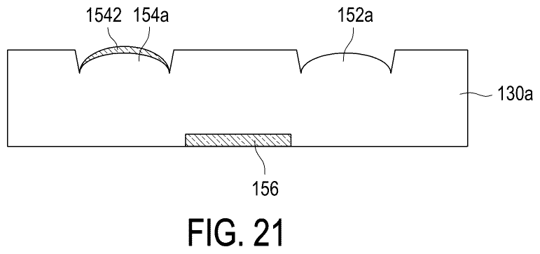

FIG. 17 to FIG. 21 illustrate partial cross sectional views of intermediate stages in the manufacturing of a lens structure on a semiconductor package according to other exemplary embodiments of the present disclosure. There are multiple methods that are suitable for forming the optical support 130a shown in FIG. 9 with the first lens structure 152 and the second lens structure 154 on the same surface of the optical support 130a. FIG. 17 to FIG. 21 merely show one of the possible methods for illustrating purpose, and the disclosure is not limited thereto.

Referring to FIG. 17, in the present embodiment, a reflector 156 is formed on the surface S2 of the optical support 130a, which is to be bonded to the encapsulated electronic die 120 as shown in FIG. 9. In some embodiments, an opening OP2 is formed on the surface S2 of the optical support 130a, in accordance with some embodiments. The opening OP2 may be formed using acceptable photolithography and etching techniques, such as by forming and patterning a photoresist and then performing an etching process using the patterned photoresist as an etching mask. The etching process may include, for example, a dry etching process and/or a wet etching process, which may be an anisotropic etch. Then, a reflective material is deposited in the opening OP2 to form the reflector 156, in accordance with some embodiments. The reflective material may include metal materials or dielectric materials that are reflective to the relevant wavelengths of light. For example, in some embodiments, the reflective material may comprise a metal such as copper, silver, gold, tungsten, cobalt, aluminum, alloys thereof, a combination thereof, or the like. The metal may be deposited using a suitable process, such as sputtering, a plating process, CVD, or the like. In some embodiments, the metal may be deposited by first depositing a seed layer and then depositing the metal on the seed layer. In other embodiments, the reflective material may comprise a dielectric material such as silicon, silicon oxide, silicon nitride, titanium oxide, tantalum oxide, titanium nitride, tantalum nitride, a combination thereof, or the like. The dielectric material may be deposited using a suitable process, such as PVD, CVD, ALD, or the like. In some embodiments, the reflective material has a thickness in the range of about 10 nm to about 1000 nm, though other thicknesses are possible. In some embodiments, the reflective material may fill the opening OP2. A planarization process (e.g., a CMP process or a grinding process) may be performed to remove excess reflective material. After performing the planarization process, top surfaces of the reflector 156 and the surface S2 of the optical support 130a may be substantially level or coplanar. In some embodiments, the reflective material has a reflectivity greater than about 90% for appropriate wavelengths of light, though other values are possible.

In other embodiment, the reflector 156 may directly deposited or sputtered over the surface S2 of the optical support 130a without forming the opening OP2, and then a filling material may be applied to cover the reflector 156 and the surface S2 of the optical support 130a. Then, a planarization process (e.g., a CMP process or a grinding process) may be performed on the filling material to flatten the surface for subsequent bonding process.

Referring to FIG. 18, the optical support 130a is then flipped over to form the first lens structure and the second lens structure on the upper surface S1 of the optical support 130a. The process of forming the first lens structure and the second lens structure may be similar to the process shown in FIG. 11 to FIG. 13. For example, a patterned polymer layer is formed on the upper surface S1 of the optical support 130a to covers regions where the first lens structure 152 and the second lens structure 154 are to be formed. Then, a reflow process is performed over the patterned polymer layer to form a plurality of polymer lens structures 160′ corresponding to the regions where the first lens structure 152 and the second lens structure 154 to be formed respectively. Each of the polymer lens structures 160′ has a surface that is curved by the surface tension of the polymer is formed as it is shown in FIG. 18. For example, the polymer lens structures 160′ may be made of polyimide (PI), polyethylene (PE), polypropylene (PP), polystyrene (PS), polyvinyl alcohol (ply alcohol); PVA), polytetrafluoroethylene (PTFE), poly (methyl methacrylate) (PMMA), polyvinyl chloride (PVC), polystyrene terephthalate (poly (ethylene terephthalate; PET), polyester, phenol resin, urea resin, urethane resin, polyurethane and the like.

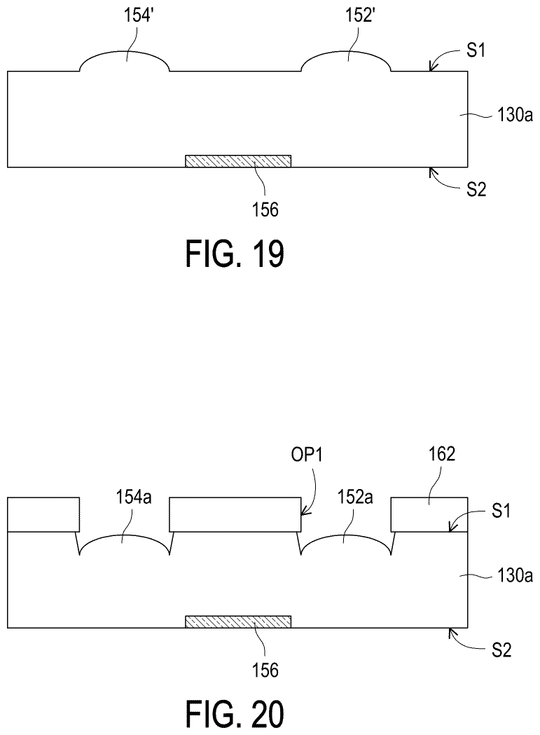

Then, referring to FIG. 19, an etching process is performed over the upper surface S1 of the optical support 130a with the polymer lens structures 160′ disposed thereon to transfer the curvy profile of each of the polymer lens structures 160 onto the upper surface S1 of the optical support 130a. As such, the first lens structure 152′ and the second lens structure 154′ as shown in FIG. 19 are formed. The first lens structure 152′ and the second lens structure 154′ protruding from the upper surface S1 of the optical support 130a may also be used as a lens for collimating and/or focusing the light beams. However, in the present embodiment, a top surface of the first lens structure 152 and the second lens structure 154 shown in FIG. 9 is substantially equal to or lower than the upper surface S1 of the optical support 130a. As such, another etching process is adopted.

Referring to FIG. 20, a patterned mask layer 162 is provided over the upper surface S1 of the optical support 130a and the patterned mask layer 162 includes a plurality of openings OP1 exposing the first lens structure 152 and the second lens structure 154 respectively. Then, another etching process is performed to form the first lens structure 152 and the second lens structure 154 shown in FIG. 20. In some embodiments, the reflector 156 is located between the first lens structure 172 and the second lens structure 174 from a top view. The etching processes may include one or more dry etching processes and/or wet etching processes. In the embodiment, the etching process includes dry etching process, which involves selective material removal by means of ion-assisted processes such as ion beam etching (IBE), reactive ion etching (RIE), and inductively coupled plasma (ICP) etching, or the like, but the disclosure is not limited thereto. Accordingly, each of the first lens structure 152 and the second lens structure 154 includes a recess dented from the upper surface S1 of the optical support 130a, and the recess includes a non-vertical sidewall and a convex bottom surface, which has a rounded or spherical shape. Then, the patterned mask layer 162 is removed.

Next, a reflective layer 1542 is formed over a surface of the second lens structure 174. Accordingly, the reflector 156 is formed underneath the first lens structure 152 to reflect light passing through the first lens structure 152 toward the second lens structure 154, and the light is reflected by the reflective layer 1542 on the second lens structure 154 to be coupled to the optical coupler 112, as it is shown in FIG. 9. In this manner, the first lens structure 152 and the second lens structure 154 are on the same surface (e.g., the upper surface S1) and can be formed simultaneously, so as to simplify the manufacturing process. The reflector 156 and the reflective layer 1542 may be formed by depositing reflective material, in accordance with some embodiments. The reflective material may comprise metal materials or dielectric materials that are reflective to the relevant wavelengths of light. For example, in some embodiments, the reflective material may comprise a metal such as copper, silver, gold, tungsten, cobalt, aluminum, alloys thereof, a combination thereof, or the like. The metal may be deposited using a suitable process, such as sputtering, a plating process, CVD, or the like. In some embodiments, the metal may be deposited by first depositing a seed layer and then depositing the metal on the seed layer. In other embodiments, the reflective material may comprise a dielectric material such as silicon, silicon oxide, silicon nitride, titanium oxide, tantalum oxide, titanium nitride, tantalum nitride, a combination thereof, or the like. The dielectric material may be deposited using a suitable process, such as PVD, CVD, ALD, or the like. In some embodiments, the reflective material has a thickness in the range of about 10 nm to about 1000 nm, though other thicknesses are possible. In some embodiments, the reflective material has a reflectivity greater than about 90% for appropriate wavelengths of light, though other values are possible.

Based on the above discussions, it can be seen that the present disclosure offers various advantages. It is understood, however, that not all advantages are necessarily discussed herein, and other embodiments may offer different advantages, and that no particular advantage is required for all embodiments.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In accordance with some embodiments of the disclosure, a semiconductor package includes a photonic die including an optical coupler, an electronic die bonded over the photonic die, and an optical support bonded over the electronic die and includes a plurality of lens structures. A light from an external optical signal source is coupled to the optical coupler sequentially through the plurality of lens structures. In one embodiment, the semiconductor package further includes an encapsulating material at least laterally encapsulating the electronic die. In one embodiment, the photonic die comprises a carrier substrate, a photonic layer comprising the optical coupler, and an interconnect structure disposed over the photonic layer. In one embodiment, the electronic die is bonded and electrically connected to the interconnect structure. In one embodiment, the plurality of lens structures comprises a first lens structure and a second lens structure disposed on two opposite surfaces of the optical support respectively. In one embodiment, the second lens structure disposed on a lower surface of the optical support bonded to the electronic die, and the second lens structure overlaps with the optical coupler from a top view. In one embodiment, the plurality of lens structures comprises a first lens structure and a second lens structure disposed on an upper surface of the optical support away from the electronic die. In one embodiment, one of the first lens structure and the second lens structure is coated with reflective layer. In one embodiment, the semiconductor package further includes a reflector disposed on a lower surface of the optical support opposite to the upper surface, wherein the light from the external optical signal source passes through the first lens structures and sequentially reflected by the reflector and the second lens structures to be coupled to the optical coupler. In one embodiment, the semiconductor package further includes a first reflector disposed on a lower surface of the optical support opposite to the upper surface and a second reflector disposed in the photonic die. In one embodiment, the light from the external optical signal source passes through the first lens structure, and sequentially reflected by the first reflector, the second lens structure, and the second reflector to be coupled to the optical coupler.

In accordance with some embodiments of the disclosure, a semiconductor package includes a photonic die comprising an optical coupler, an electronic die bonded over the photonic die, and an optical support bonded over the electronic die. The optical support includes a first lens structure and a second lens structure configured to couple light to the optical coupler sequentially through the first lens structure and the second lens structure, wherein a size of the first lens structure is substantially greater than a size of the second lens structure. In one embodiment, each of the first lens structure and the second lens structure comprises a recess dented from an outer surface of the optical support. In one embodiment, the recess comprises a non-vertical sidewall and a convex bottom surface. In one embodiment, the first lens structure and the second lens structure are disposed on two opposite surfaces of the optical support respectively. In one embodiment, the first lens structure and the second lens structure are both disposed on an upper surface of the optical support away from the electronic die.

In accordance with some embodiments of the disclosure, a manufacturing method of a semiconductor package include: providing a photonic die; bonding an electronic die over the photonic die; providing an encapsulating material over the photonic die to form an encapsulated electronic die; forming a first lens structure and a second lens structure over an optical support; and bonding the optical support over the encapsulated electronic die. The photonic die includes an optical coupler. The encapsulating material at least laterally encapsulates the electronic die. Light from an external optical signal source is coupled to the optical coupler sequentially through the first lens structure and the second lens structure. In one embodiment, forming the first lens structure and the second lens structure over the optical support further includes: forming a second lens structure on a lower surface of the optical support to be bonded to the encapsulated electronic die, wherein the second lens structure comprises a recess; forming a first lens structure on an upper surface of the optical support opposite to the lower surface; and providing a filling material for filling the recess, wherein the lower surface of the optical support with the second lens structure filled with the filling material is bonded to the encapsulated electronic die. In one embodiment, the method further includes: forming a reflector on a lower surface of the optical support to be bonded to the encapsulated electronic die, wherein forming the first lens structure and the second lens structure over the optical support further comprising: forming a first lens structure and a second lens structure on an upper surface of the optical support opposite to the lower surface; and forming a reflective layer over a surface of the second lens structure, wherein the reflector is located between the first lens structure and the second lens structure from a top view. In one embodiment, forming each of the first lens structure and the second lens structure over the optical support includes: forming a patterned polymer layer over the optical support; performing a reflow process over the patterned polymer layer to form a polymer lens structure; performing an etching process over a surface of the optical support with the polymer lens structure to transfer a profile of the polymer lens structure onto the optical support.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a photonic die comprising an optical coupler;
an electronic die bonded over the photonic die; and
an optical support bonded over the electronic die and comprising a plurality of lens structures, wherein light from an external optical signal source is coupled to the optical coupler sequentially through the plurality of lens structures.

2. The semiconductor package as claimed in claim 1, further comprising an encapsulating material at least laterally encapsulating the electronic die.

3. The semiconductor package as claimed in claim 1, wherein the photonic die comprises a carrier substrate, a photonic layer comprising the optical coupler, and an interconnect structure disposed over the photonic layer.

4. The semiconductor package as claimed in claim 3, wherein the electronic die is bonded and electrically connected to the interconnect structure.

5. The semiconductor package as claimed in claim 1, wherein the plurality of lens structures comprises a first lens structure and a second lens structure disposed on two opposite surfaces of the optical support respectively.

6. The semiconductor package as claimed in claim 5, wherein the second lens structure disposed on a lower surface of the optical support bonded to the electronic die, and the second lens structure overlaps with the optical coupler from a top view.

7. The semiconductor package as claimed in claim 1, wherein the plurality of lens structures comprises a first lens structure and a second lens structure disposed on an upper surface of the optical support away from the electronic die.

8. The semiconductor package as claimed in claim 1, wherein one of the first lens structure and the second lens structure is coated with a reflective layer.

9. The semiconductor package as claimed in claim 7, further comprising a reflector disposed on a lower surface of the optical support opposite to the upper surface, wherein the light from the external optical signal source passes through the first lens structure and sequentially reflected by the reflector and the second lens structure to be coupled to the optical coupler.

10. The semiconductor package as claimed in claim 7, further comprising a first reflector disposed on a lower surface of the optical support opposite to the upper surface and a second reflector disposed in the photonic die.

11. The semiconductor package as claimed in claim 10, wherein the light from the external optical signal source passes through the first lens structure, and sequentially reflected by the first reflector, the second lens structure, and the second reflector to be coupled to the optical coupler.

12. A semiconductor package, comprising:
a photonic die comprising an optical coupler;
an encapsulated electronic die bonded over the photonic die; and
an optical support bonded over the encapsulated electronic die and comprises a first lens structure and a second lens structure configured to couple light to the optical coupler sequentially.

13. The semiconductor package as claimed in claim 12, wherein each of the first lens structure and the second lens structure comprises a recess dented from an outer surface of the optical support.

14. The semiconductor package as claimed in claim 13, wherein the recess comprises a non-vertical sidewall and a convex bottom surface.

15. The semiconductor package as claimed in claim 12, wherein the first lens structure and the second lens structure are disposed on two opposite surfaces of the optical support respectively, and a size of the first lens structure is substantially greater than a size of the second lens structure.

16. The semiconductor package as claimed in claim 12, wherein the first lens structure and the second lens structure are both disposed on an upper surface of the optical support away from the encapsulated electronic die.

17. A manufacturing method of a semiconductor package, comprising:
providing a photonic die, wherein the photonic die comprises an optical coupler;
bonding an electronic die over the photonic die;
providing an encapsulating material over the photonic die to form an encapsulated electronic die, wherein the encapsulating material at least laterally encapsulates the electronic die;
forming a first lens structure and a second lens structure over an optical support; and
bonding the optical support over the encapsulated electronic die, wherein light from an external optical signal source is coupled to the optical coupler sequentially through the first lens structure and the second lens structure.

18. The manufacturing method of the semiconductor package as claimed in claim 17, wherein forming the first lens structure and the second lens structure over the optical support further comprising:
forming a second lens structure on a lower surface of the optical support to be bonded to the encapsulated electronic die, wherein the second lens structure comprises a recess;
forming a first lens structure on an upper surface of the optical support opposite to the lower surface; and
providing a filling material for filling the recess, wherein the lower surface of the optical support with the second lens structure filled with the filling material is bonded to the encapsulated electronic die.

19. The manufacturing method of the semiconductor package as claimed in claim 17, further comprising forming a reflector on a lower surface of the optical support to be bonded to the encapsulated electronic die, wherein forming the first lens structure and the second lens structure over the optical support further comprising:
forming a first lens structure and a second lens structure on an upper surface of the optical support opposite to the lower surface; and
forming a reflective layer over a surface of the second lens structure, wherein the reflector is located between the first lens structure and the second lens structure from a top view.

20. The manufacturing method of the semiconductor package as claimed in claim 17, wherein forming each of the first lens structure and the second lens structure over the optical support comprises:
forming a patterned polymer layer over the optical support;
performing a reflow process over the patterned polymer layer to form a polymer lens structure;
performing an etching process over a surface of the optical support with the polymer lens structure to transfer a profile of the polymer lens structure onto the optical support.
